(19) United States
(12) Patent Application Publication
(10) Pub. No.: US 2025/0194001 A1
(43) Pub. Date: Jun. 12, 2025

(54) PRINTED CIRCUIT BOARD

(71) Applicant: SAMSUNG ELECTRO-MECHANICS CO., LTD., Suwon-si (KR)

(72) Inventors: Kyung Moon JUNG, Suwon-si (KR); Dong Hyeon LEE, Suwon-si (KR); Chi Hyeon JEONG, Suwon-si (KR)

(73) Assignee: SAMSUNG ELECTRO-MECHANICS CO., LTD., Suwon-si (KR)

(21) Appl. No.: 18/960,547

(22) Filed: Nov. 26, 2024

(30) Foreign Application Priority Data
Dec. 6, 2023 (KR) 10-2023-0175815

(51) Int. Cl. H05K 1/02; H05K 1/03; H05K 1/11

(52) U.S. Cl. CPC H05K 1/0271; H05K 1/0306; H05K 1/115; H05K 2201/0183; H05K 2201/068

(57) ABSTRACT

A printed circuit board includes a substrate having first and second external portions opposite to each other in a length direction, a first insulating layer disposed on an upper side of the substrate, a second insulating layer disposed on a lower side of the substrate, a first insulating material covering at least a portion of the first external portion of the substrate, and a second insulating material covering at least a portion of the second external portion of the substrate. The first and second insulating layers respectively have a coefficient of thermal expansion higher than that of the substrate. The first and second insulating materials respectively have a coefficient of thermal expansion lower than that of the substrate.

### CROSS-REFERENCE TO RELATED APPLICATION(S)

This application claims the benefit of priority to Korean Patent Application No. 10-2023-0175815 filed on Dec. 6, 2023 in the Korean Intellectual Property Office, the disclosure of which is incorporated herein by reference in its entirety.

### TECHNICAL FIELD

The present disclosure relates to a printed circuit board.

### BACKGROUND

Currently, package substrates used in high-end semiconductor products have been required to implement a microcircuit therein to respond to a large number of input/output terminals, and have also been required to have a large area so as to mount various chips thereon. A general package substrate using an organic material as a core may have difficulty in implementing a microcircuit therein, and may have limitations in controlling warpage due to low modulus or the like. Accordingly, research has been conducted on a package substrate using an inorganic material, such as glass, as a core instead of the organic material. However, the glass material is brittle, and thus may be vulnerable to external impacts or residual stress caused by a process.

### SUMMARY

An aspect of the present disclosure provides a printed circuit board preventing cracks in response to external impacts or residual stress caused by a process, even when an inorganic material such as glass is used as a core.

According to an aspect of the present disclosure, a substrate including an inorganic material, such as glass, may be used as a core, insulating layers may be respectively built up on upper and lower sides of the substrate, and an insulating material, including a material having a coefficient of thermal expansion relatively lower than that of the substrate, may be disposed at an edge portion of the substrate, thereby reducing tensile stress caused by contraction behavior of an insulating layer having a high coefficient of thermal expansion.

For example, a printed circuit board according to an aspect of the present disclosure may include a substrate having first and second external portions opposite to each other in a length direction, a first insulating layer disposed on an upper side of the substrate, second insulating layer disposed on a lower side of the substrate, a first insulating material covering at least a portion of the first external portion of the substrate, and a second insulating material covering at least a portion of the second external portion of the substrate. The first and second insulating layers may respectively have a coefficient of thermal expansion higher than that of the substrate. The first and second insulating materials may respectively have a coefficient of thermal expansion lower than that of the substrate.

For example, a printed circuit board according to another aspect of the present disclosure may include a substrate having first and second external portions opposite to each other in a length direction, a first insulating layer disposed on an upper side of the substrate, a second insulating layer disposed on a lower side of the substrate, a first insulating material covering at least a portion of the first external portion of the substrate, and a second insulating material covering at least a portion of the second external portion of the substrate. At least a portion of an external surface of each of the first and second external portions of the substrate may be exposed from the first and second insulating materials.

According to example embodiments of the present disclosure, a printed circuit board may prevent cracks in response to external impacts or residual stress caused by a process, even when an inorganic material, such as glass, is used as a core.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIG. 3 is a schematic cross-sectional view of an example of a printed circuit board;

FIGS. 4A and 4B are schematic cross-sectional views of the printed circuit board of FIG. 3, when viewed in directions A and B, respectively;

FIG. 5 is a schematic cross-sectional view of another example of a printed circuit board;

FIGS. 6A and 6B are schematic cross-sectional views of the printed circuit board of FIG. 5, when viewed in directions C and D, respectively;

FIGS. 7A and 7B schematically illustrate a thermal stress generation mechanism and a thermal stress analysis result of a glass substrate, when insulating layers are disposed on an upper side and a lower side of the glass substrate, respectively;

FIGS. 8A and 8B schematically illustrate a thermal stress generation mechanism and a thermal stress analysis result of a glass substrate in a structure of the printed circuit board of FIG. 3, respectively; and

FIGS. 9A and 9B schematically illustrate a thermal stress generation mechanism and a thermal stress analysis result of a glass substrate in a structure of the printed circuit board of FIG. 5, respectively.

### DETAILED DESCRIPTION

Hereinafter, example embodiments of the present disclosure are described with reference to the accompanying drawings. The shapes and sizes of components in the drawings may be exaggerated or reduced for clearer description.

### Electronic Device

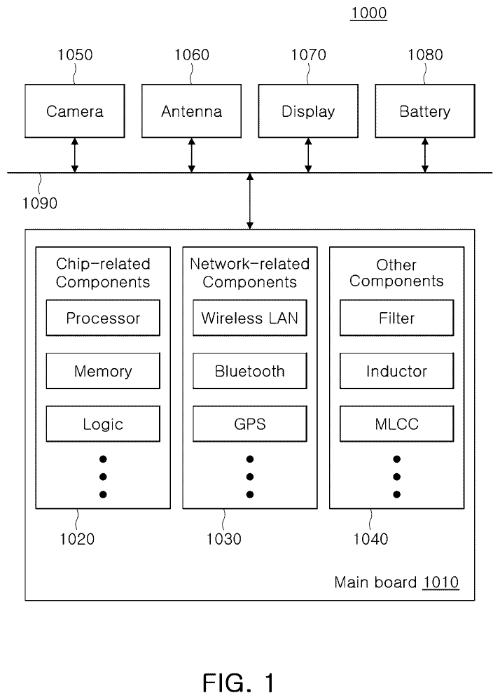

FIG. 1 is a schematic block diagram of an example of an electronic device system.

Referring to the drawing, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high-frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

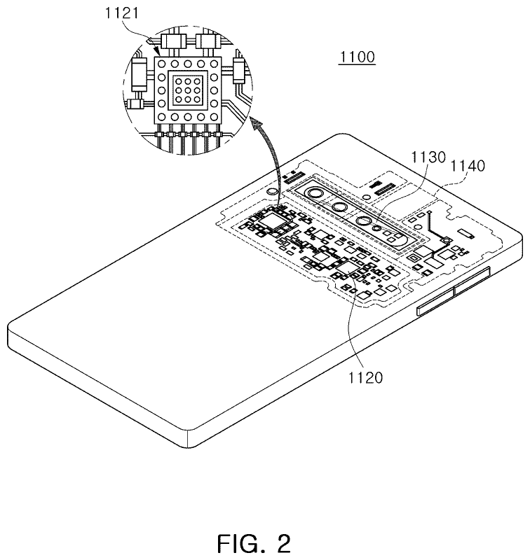

FIG. 2 is a schematic perspective view of an example of an electronic device.

Referring to the drawing, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices, as described above.

### Printed Circuit Board

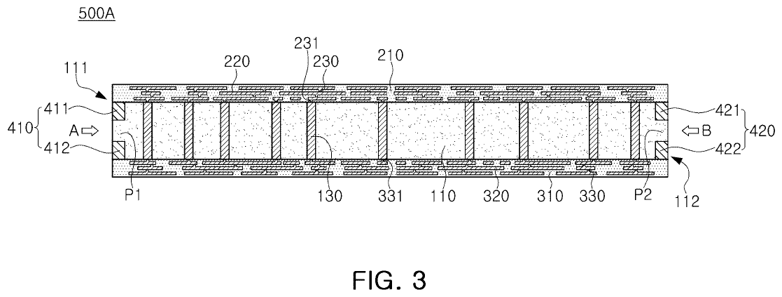

FIG. 3 is a schematic cross-sectional view of an example of a printed circuit board.

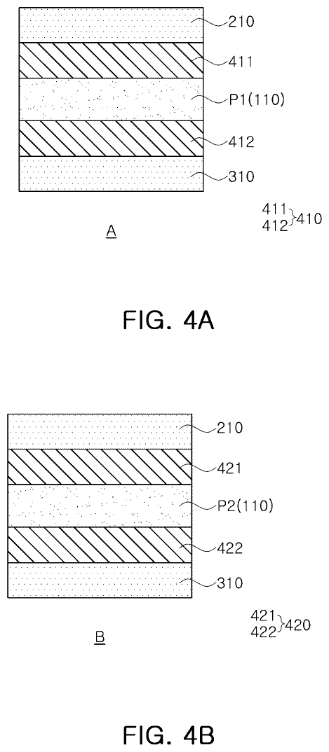

FIGS. 4A and 4B are schematic cross-sectional views of the printed circuit board of FIG. 3, when viewed in directions A and B, respectively.

Referring to the drawings, the printed circuit board 500A according to an example may include a substrate 110 having first and second external portions 111 and 112 opposite to each other in a length direction, a first insulating layer 210 disposed on an upper side of the substrate 110, a second insulating layer 310 disposed on a lower side of the substrate 110, a first insulating material 410 covering at least a portion of the first external portion 111, and a second insulating material 420 covering at least a portion of the second external portion 112. The first and second external portions 111 and 112 may respectively have predetermined regions from both ends of the substrate 110 in the length direction, in cross-section. The predetermined regions of the first and second external portions 111 and 112 may respectively have sizes approximately corresponding to those of the first and second insulating materials 410 and 420. The first and second insulating layers 210 and 310 may respectively have a coefficient of thermal expansion higher than that of the substrate 110, and the first and second insulating materials 410 and 420 may respectively have a coefficient of thermal expansion lower than that of the substrate 110. For example, the first and second insulating materials 410 and 420, having a coefficient of thermal expansion lower than that of the substrate 110, may be respectively disposed to be adjacent to edges of the first and second external portions 111 and 112 of the substrate 110, thereby reducing tensile stress generated by contraction behavior of the first and second insulating layers 210 and 310 having a coefficient of thermal expansion higher than that of the substrate. Accordingly, even when an inorganic material such as glass is used as a material of the substrate 110, cracks or the like may be prevented in response to external impacts or residual stress caused by a process. When the inorganic material such as glass is used as the material of the substrate 110, it may be more advantageous for warpage control due to a high modulus and a high glass transition temperature, and the substrate 110 may have a large area. In addition, due to low surface roughness and high processability of the substrate 110, it may be more advantageous in implementing a microcircuit.

Respective components in a printed circuit board that needs to be measured may be cut into the same size to obtain a sample, and coefficient of thermal expansions of respective samples may be measured using the same thermometer analysis device, such as TMA 8310, TATMA Q400, or the like. For example, a substrate, an insulating layer, an insulating material, and the like in a manufactured printed circuit board may be cut into the same size afterwards to respective samples, and the respective samples may be cut such that coefficient of thermal expansions of the respective samples are measured in the same direction, for example, in a length direction of the manufactured printed circuit board. In this case, the coefficient of thermal expansions of the respective samples may be measured under the same conditions. For example, after the respective samples are mounted in the thermometer analysis device, the samples may be heated from room temperature to 170° C. in a tensile mode of 0.1 N, and may then be cooled to room temperature. During such a process, the coefficient of thermal expansions of the respective samples may be measured by obtaining an average value of coefficient of thermal expansions of the respective samples within a range of 50° C. to 80° C., but the conditions are not limited thereto.

The first insulating material 410 may include a first-first insulating material 411 disposed on an upper side of the first external portion 111, and a first-second insulating material 412 disposed on a lower side of the first external portion 111. The first-first insulating material 411 and the first-second insulating material 412 may be spaced apart from each other with the first external portion 111 interposed therebetween. The second insulating material 420 may include a second-first insulating material 421 disposed on an upper side of the second external portion 112, and a second-second insulating material 422 disposed on a lower side of the second external portion 112. The second-first insulating material 421 and the second-second insulating material 422 may be spaced apart from each other with the second external portion 112 interposed therebetween. The first and second external portions 111 and 112 of the substrate 110 may have first and second protrusion portions P1 and P2, respectively. A thickness of each of the first and second protrusion portions P1 and P2 may be lower than that of a remaining region of the substrate 110. The first-first insulating material 411 may be disposed between the first protrusion portion P1 and the first insulating layer 210, and the first-second insulating material 412 may be disposed between the first protrusion portion P1 and the second insulating layer 310. The second-first insulating material 421 may be disposed between the second protrusion portion P2 and the first insulating layer 210, and the second-second insulating material 422 may be disposed between the second protrusion portion P2 and the second insulating layer 310. At least a portion of an external surface of each of the first and second protrusion portions P1 and P2 and at least a portion of an external surface of each of the first and second insulating layers 210 and 310 may be exposed from the first and second insulating materials 410 and 420. Through such a structure, the above-described technical effect may be effectively realized.

The first and second insulating materials 410 and 420 may be disposed to be adjacent not only to edge portions of both external portions 111 and 112 of the substrate 110 in a length direction, but also to edge portions of both external portions of the substrate 110 in a width direction. For example, the first and second insulating materials 410 and 420, for example, the first-first, first-second, second-first, second-second insulating materials 411, 412, 421, and 422 may also be disposed to have a cross-sectional shape in a width-thickness direction, substantially the same as the above-described cross-sectional shape in a length-thickness direction. The first-first and second-first insulating materials 411 and 421 may be connected to each other, and the first-second and second-second insulating materials 412 and 422 may be connected to each other, as necessary. For example, the first and second insulating materials 410 and 420 may be disposed to continuously surround the external portions of the substrate 110 in plan view. However, the present disclosure is not limited thereto. When a lamination direction of the first and second insulating layers 210 and 310 with respect to the substrate 110 is a thickness direction, a length direction may be one direction, perpendicular to the thickness direction, and a width direction may be another direction, perpendicular to both the length direction and the thickness direction. In this case, the length direction may be substantially parallel to at least one external surface of the printed circuit board 500A, and the thickness direction may be substantially parallel to at least another external surface of the printed circuit board 500A.

The printed circuit board 500A according to an example may further include a plurality of first wiring layers 220 disposed in the first insulating layer 210, a plurality of first via layers 230 disposed in the first insulating layer 210, the plurality of first via layers 230 respectively connected to at least one of the plurality of first wiring layers 220, a plurality of second wiring layers 320 disposed in the second insulating layer 310, a plurality of second via layers 330 disposed in the second insulating layer 310, the plurality of second via layers 330 respectively connected to at least one of the plurality of second wiring layers 320, and at least one through-via 130 passing through the substrate 110. For example, the printed circuit board 500A according to an example may be a multilayer circuit board having a large area, and thus may be used as a package substrate. At least a portion of a lowermost first via layer 231, among the plurality of first via layers 230, may be connected to an upper side of the through-via 130. In addition, at least a portion of an uppermost second via layer 331, among the plurality of second via layers 330, may be connected to a lower side of the through-via 130. For example, a wiring layer may not be directly formed on upper and lower surfaces of the substrate 110, and the through-via 130 may be directly connected to each of the lowermost first via layer 231 and the uppermost second via layer 331.

Hereinafter, components of the printed circuit board 100A according to an example will be described in more detail with reference to the drawings.

The substrate 110 may be a core layer. The substrate 110 may include an inorganic insulating material. The inorganic insulating material may be glass, silicon (Si), ceramic, or the like. For example, the substrate 110 may include a glass substrate, a silicon substrate, or a ceramic substrate. The substrate may preferably include a glass substrate, and more preferably, a glass substrate having a coefficient of thermal expansion (CTE) of about 6 ppm/° C. to about 10 ppm/° C. The glass substrate may include glass, and glass may include, for example, pure silicon dioxide (about 100% SiO₂), soda lime glass, borosilicate glass, alumino-silicate glass, or the like. However, the present disclosure is not limited thereto, and an alternative glass material, such as fluorine glass, phosphate glass, chalcogen glass, or the like, may also be used as a material of the glass layer. In addition, other additives may be further included to form glass having specific physical properties. The above-described additives may include calcium carbonate (for example, lime) and sodium carbonate (for example, soda), as well as magnesium, calcium, manganese, aluminum, lead, boron, iron, chromium, potassium, sulfur, and antimony, and carbonate and/or an oxide of the above-described elements and other elements. Glass may be distinguished from a glass fiber (glass cloth and/or glass fabric) included in an organic insulating material. In addition, the silicon substrate may include silicon (Si), and may include an oxide layer formed on silicon (Si), as necessary. In addition, the silicon substrate may include a nitride layer formed on the oxide layer. The oxide layer may include a silicon oxide film, and the nitride layer may include a silicon nitride film, but the present disclosure is not limited thereto. In addition, the ceramic substrate may include ceramic, and ceramic may include, for example, alumina (Al₂O₃), aluminum nitride (AlN), silicon carbide (Sic), silicon nitride (Si₃N₄), or the like, but the present disclosure is not limited thereto.

The through-via 130 may include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The through-via 130 may be a through-glass via (TGV), a through-silicon via (TSV), or the like, depending on the material of the substrate 110. A plugging material may be disposed in the through-via 130, as necessary, and the plugging material may include an insulating material or a conductive material. The through-via 130 may have a substantially vertical side surface in cross-section, and may have a pillar shape such as a cylinder, an elliptical pillar, a square pillar, or the like, but the present disclosure is not limited thereto. The through-via 130 may perform various functions according to a design thereof. For example, a ground via, a power via, a signal via, or the like may be included. The through-via 130 may include a sputtering layer and an electrolytic plating layer (or electrolytic copper). An electroless plating layer (or chemical copper) may be included instead of the sputtering layer, or both may be included, as necessary. A plurality of through-vias 130 may be provided. In this case, the through-vias 130 may include substantially the same metal.

The first and second insulating layers 210 and 310 may be respectively a build-up insulating layer. The first and second insulating layers 210 and 310 may respectively include an organic insulating material. The organic insulating material may include a thermosetting resin such as an epoxy resin, a thermoplastic resin such as polyimide, or an inorganic filler, an organic filler, and/or a glass fiber (glass cloth and/or glass fabric), together with the resin. For example, the organic insulating material may be a non-photosensitive insulating material such as an Ajinomoto build-up film (ABF), a prepreg (PPG), or the like, but the present disclosure is not limited thereto, and other polymer materials may also be used. The first and second insulating layers 210 and 310 may preferably include an ABF, respectively, and more preferably, an ABF having a coefficient of thermal expansion (CTE), higher than about 10 ppm/° C., for example, about 35 ppm/° C. to about 45 ppm/° C. The first and second insulating layers 210 and 310 may respectively include a plurality of insulating layers, and respective insulating layers may include substantially the same organic insulating material, and thus may have an unclear interlayer boundary therebetween.

The first and second wiring layers 220 and 320 may be respectively a build-up wiring layer. The first and second wiring layers 220 and 320 may respectively include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The first and second wiring layers 220 and 320 may respectively perform various functions according to a design thereof. For example, a signal pattern, a power pattern, a ground pattern, or the like may be included. The patterns may respectively have various forms such as a line, a plane, a pad, and the like. The first and second wiring layers 220 and 320 may respectively include a seed layer and a plating layer formed on the seed layer. The seed layer may be an electroless plating layer (or chemical copper) and/or a sputtering layer, and the plating layer may be an electrolytic plating layer (or electrolytic copper), but the present disclosure is not limited thereto. The first and second wiring layers 220 and 320 may respectively include a plurality of wiring layers, and respective wiring layers may include substantially the same metal.

The first and second via layers 230 and 330 may be respectively a build-up via layer. The first and second via layers 230 and 330 may respectively include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The first and second via layers 230 and 330 may respectively include a filled via filling a via hole, but may also include a conformal via disposed along a wall surface of the via hole. The first and second via layers 230 and 330 may respectively perform various functions according to a design thereof. For example, a ground via, a power via, a signal via, or the like may be included. The first and second via layers 230 and 330 may be tapered in opposite directions. For example, a width of an upper end of the first via layer 230 may be greater than a width of a lower end of the first via layer 230 in cross-section, and a width of a lower end of the second via layer 330 may be greater than a width of an upper end of the second via layer 330 in cross-section. The first and second via layers 133 and 134 may respectively include an electroless plating layer (or chemical copper) and an electrolytic plating layer (or electrolytic copper). Instead of the electroless plating layer (or chemical copper), a sputtering layer may be included, or both may be included. The first and second via layers 230 and 330 may respectively include a plurality of via layers, and respective via layers may include substantially the same metal.

The first and second insulating materials 410 and 420 may be respectively a stress reducing layer. The first and second insulating materials 410 and 420 may respectively include a material having a low coefficient of thermal expansion. For example, the first and second insulating materials 410 and 420 may respectively include an organic insulating material having a low coefficient of thermal expansion, an inorganic insulating material having a low coefficient of thermal expansion, and the like. For example, the first and second insulating materials may respectively include a PPG, an ABF, or ceramic having a coefficient of thermal expansion less than 6 ppm/° C., for example, about 1 ppm/° C. to about 5 ppm/° C. The first insulating material 410 may include a first-first insulating material 411 and a first-second insulating material 412, and the second insulating material 420 may include a second-first insulating material 421 and a second-second insulating material 422. The first-first insulating material 411, the first-second insulating material 412, the second-first insulating material 421, and the second-second insulating material 422 may include substantially the same organic or inorganic insulating material, and thus may have substantially the same thermal expansion coefficient.

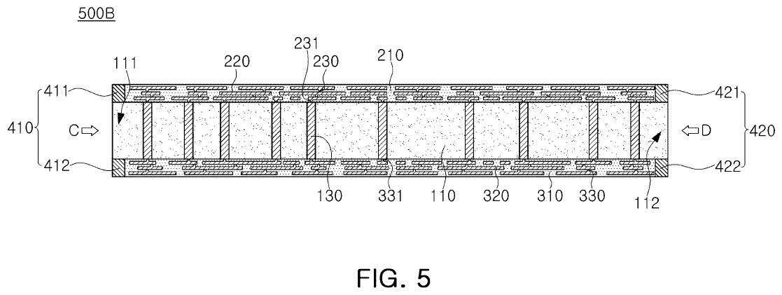

FIG. 5 is a schematic cross-sectional view of another example of a printed circuit board.

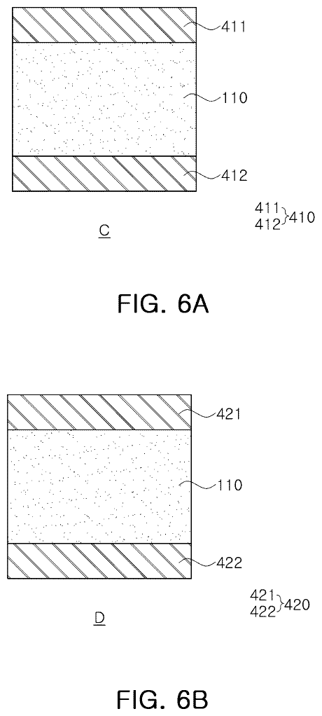

FIGS. 6A and 6B are schematic cross-sectional views of the printed circuit board of FIG. 5, when viewed in directions C and D, respectively.

Referring to the drawings, a printed circuit board 500B according to another example may include a substrate 110 having first and second external portions 111 and 112 opposite to each other in a length direction, a first insulating layer 210 disposed on an upper side of the substrate 110, a second insulating layer 310 disposed on a lower side of the substrate 110, a first insulating material 410 covering at least a portion of the first external portion 111, and a second insulating material 420 covering at least a portion of the second external portion 112. The first and second external portions 111 and 112 may respectively have predetermined regions from both ends of the substrate 110 in the length direction, in cross-section. The predetermined regions of the first and second external portions 111 and 112 may respectively have sizes approximately corresponding to those of the first and second insulating materials 410 and 420. The first and second insulating layers 210 and 310 may respectively have a coefficient of thermal expansion higher than that of the substrate 110, and the first and second insulating materials 410 and 420 may respectively have a coefficient of thermal expansion lower than that of the substrate 110. For example, the first and second insulating materials 410 and 420, having a coefficient of thermal expansion lower than that of the substrate 110, may be respectively disposed to be adjacent to edges of the first and second external portions 111 and 112 of the substrate 110, thereby reducing tensile stress generated by contraction behavior of the first and second insulating layers 210 and 310 having a coefficient of thermal expansion higher than that of the substrate. Accordingly, even when an inorganic material such as glass is used as a material of the substrate 110, cracks or the like may be prevented in response to external impacts or residual stress caused by a process. When the inorganic material such as glass is used as the material of the substrate 110, it may be more advantageous for warpage control due to a high modulus and a high glass transition temperature, and the substrate 110 may have a large area. In addition, due to low surface roughness and high processability of the substrate 110, it may be more advantageous in implementing a microcircuit.

The first insulating material 410 may include a first-first insulating material 411 disposed on an upper side of the first external portion 111, and a first-second insulating material 412 disposed on a lower side of the first external portion 111. The first-first insulating material 411 and the first-second insulating material 412 may be spaced apart from each other with the first external portion 111 interposed therebetween. The second insulating material 420 may include a second-first insulating material 421 disposed on an upper side of the second external portion 112, and a second-second insulating material 422 disposed on a lower side of the second external portion 112. The second-first insulating 421 material and the second-second insulating material 422 may be spaced apart from each other with the second external portion 112 interposed therebetween. The first-first insulating material 411 may be disposed on an upper surface of the first external portion 111 of the substrate 110, and may cover at least a portion of an external surface of the first insulating layer 210. The first-second insulating material 412 may be disposed on a lower surface of the first external portion 111 of the substrate 110, and may cover at least a portion of an external surface of the second insulating layer 310. The second-first insulating material 421 may be disposed on an upper surface of the second external portion 112 of the substrate 110, and may cover at least another portion of the external surface of the first insulating layer 210. The second-second insulating material 422 may be disposed on a lower surface of the second external portion 112 of the substrate 110, and may cover at least another portion of the external surface of the second insulating layer 310. At least a portion of an external surface of each of the first and second external portions 111 and 112 of the substrate may be exposed from the first and second insulating materials 410 and 420. Through such a structure, the above-described technical effect may be effectively realized.

The first and second insulating materials 410 and 420 may be disposed to be adjacent not only to edge portions of both external portions 111 and 112 of the substrate 110 in a length direction, but also to edge portions of both external portions of the substrate 110 in a width direction. For example, the first and second insulating materials 410 and 420, for example, the first-first, first-second, second-first, second-second insulating materials 411, 412, 421, and 422 may also be disposed to have a cross-sectional shape in a width-thickness direction, substantially the same as the above-described cross-sectional shape in a length-thickness direction. The first-first and second-first insulating materials 411 and 421 may be connected to each other, and the first-second and second-second insulating materials 412 and 422 may be connected to each other, as necessary. For example, the first and second insulating materials 410 and 420 may be disposed to continuously surround the external portions of the substrate 110 in plan view. However, the present disclosure is not limited thereto. When a lamination direction of the first and second insulating layers 210 and 310 with respect to the substrate 110 is a thickness direction, a length direction may be one direction, perpendicular to the thickness direction, and a width direction may be another direction, perpendicular to both the length direction and the thickness direction. In this case, the length direction may be substantially parallel to at least one external surface of the printed circuit board 500B, and the thickness direction may be substantially parallel to at least another external surface of the printed circuit board 500B.

The printed circuit board 500B according to another example may further include a plurality of first wiring layers 220 disposed in the first insulating layer 210, a plurality of first via layers 230 disposed in the first insulating layer 210, the plurality of first via layers 230 respectively connected to at least one of the plurality of first wiring layers 220, a plurality of second wiring layers 320 disposed in the second insulating layer 310, a plurality of second via layers 330 disposed in the second insulating layer 310, the plurality of second via layers 330 respectively connected to at least one of the plurality of second wiring layers 320, and at least one through-via 130 passing through the substrate 110. For example, the printed circuit board 500B according to another example may be a multilayer circuit board having a large area, and thus may be used as a package substrate. At least a portion of a lowermost first via layer 231, among the plurality of first via layers 230, may be connected to an upper side of the through-via 130. In addition, at least a portion of an uppermost second via layer 331, among the plurality of second via layers 330, may be connected to a lower side of the through-via 130. For example, a wiring layer may not be directly formed on upper and lower surfaces of the substrate 110, and the through-via 130 may be directly connected to each of the lowermost first via layer 231 and the uppermost second via layer 331.

Descriptions of components of the printed circuit board 500B according to another example may be substantially the same as descriptions of components of the printed circuit board 500A according to an example.

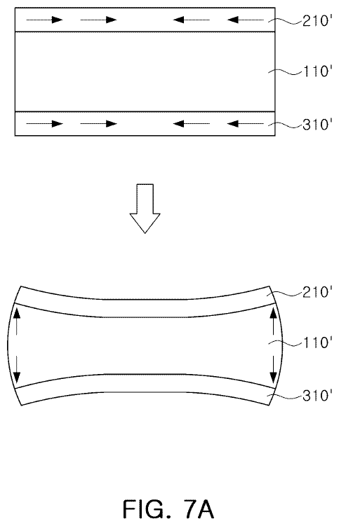

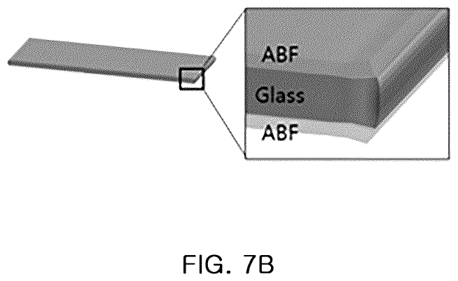

FIGS. 7A and 7B schematically illustrate a thermal stress generation mechanism and a thermal stress analysis result of a glass substrate, when insulating layers are disposed on an upper side and a lower side of the glass substrate, respectively.

Referring to the drawings, as compared to a glass substrate 110′ having a coefficient of thermal expansion of about 7.2 ppm/° C., insulating layers 210′ and 310′ may have a relatively high coefficient of thermal expansion. For example, an ABF may have a coefficient of thermal expansion of about 39 ppm/° C. When a panel in which the ABF is disposed on upper and lower sides of the glass substrates 110′ are cut in units, high tensile stress may occur in an edge portion of the glass substrate 110 due to strong contraction behavior of the insulating layers 210′ and 310′, and thus cracks may occur in a horizontal direction of the glass substrate 110′, for example, in a length direction and/or a width direction of the glass substrate 110′. Here, normalized tensile stress may be about 1.00.

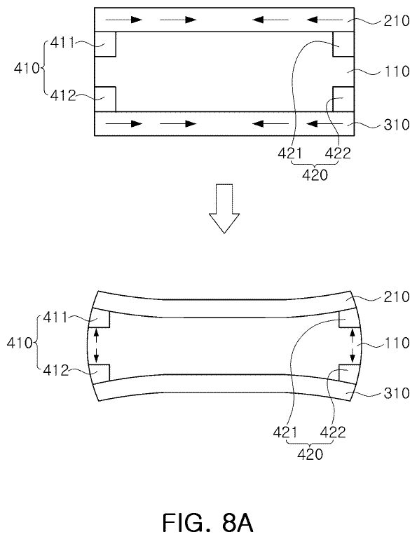

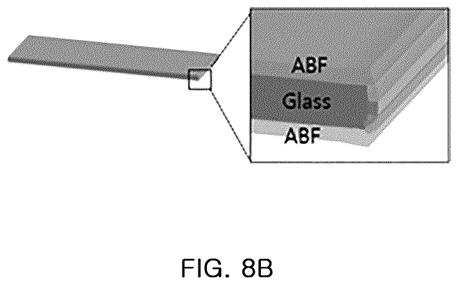

FIGS. 8A and 8B schematically illustrate a thermal stress generation mechanism and a thermal stress analysis result of a glass substrate in a structure of the printed circuit board of FIG. 3, respectively.

Referring to the drawing, as compared to a glass substrate 110 having a coefficient of thermal expansion of about 7.2 ppm/° C., insulating materials 410 and 420 having a relatively low coefficient of thermal expansion, for example, a PPG having a coefficient of thermal expansion of about 4 ppm/° C. and a modulus of about 14 GPa may be disposed as the first and second insulating materials 410 and 420 of the printed circuit board of FIG. 3. In this case, as compared to the glass substrate 110, insulating layers 210 and 310 may have a relatively high coefficient of thermal expansion. For example, an ABF may have a coefficient of thermal expansion of about 39 ppm/° C. When a panel in which the ABF is disposed as first and second insulating layers 210 and 310 of the printed circuit board of FIG. 3 is cut into units, contraction behavior of the first and second insulating layers 210 and 310 at an edge portion of the glass substrate 110 may be reduced, and thus the tensile stress applied thereto may be reduced, thereby preventing cracks from occurring in a horizontal direction of the glass substrate 110, for example, in a length direction and/or a width direction of the glass substrate 110. Here, normalized tensile stress may be about 0.60.

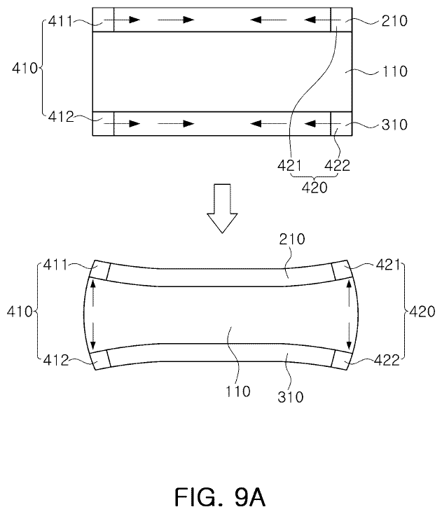

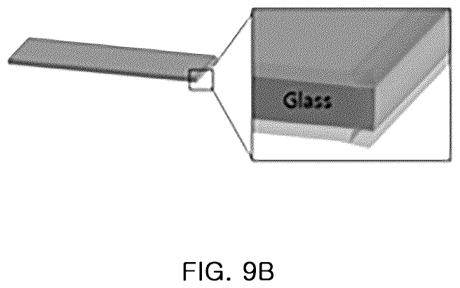

FIGS. 9A and 9B schematically illustrate a thermal stress generation mechanism and a thermal stress analysis result of a glass substrate in a structure of the printed circuit board of FIG. 5, respectively.

Referring to the drawings, as compared to a glass substrate 110 having a coefficient of thermal expansion of about 7.2 ppm/° C., insulating materials 410 and 420 having a relatively low coefficient of thermal expansion, for example, a PPG having a coefficient of thermal expansion of about 4 ppm/° C. and a modulus of about 14 GPa may be disposed as the first and second insulating materials 410 and 420 of the printed circuit board of FIG. 5. In this case, as compared to the glass substrate 110, insulating layers 210 and 310 may have a relatively high coefficient of thermal expansion. For example, an ABF may have a coefficient of thermal expansion of about 39 ppm/° C. When a panel in which the ABF is disposed as first and second insulating layers 210 and 310 of the printed circuit board of FIG. 5 is cut in units, contraction behavior of the first and second insulating layers 210 and 310 at an edge portion of the glass substrate 110 may be reduced, and thus the tensile stress applied thereto may be reduced, thereby preventing cracks from occurring in a horizontal direction of the glass substrate 110, for example, in a length direction and/or a width direction of the glass substrate 110. Here, normalized tensile stress may be about 0.57.

As used herein, the terms “cover,” “to cover,” and “covering” may include entirely covering as well as at least partially covering, and may include directly covering as well as indirectly covering. In addition, the terms “fill,” to fill,” and “filling” may include not only entirely filling, but also approximately filling, for example, may include a case in which some voids, pores or the like are present. In addition, the terms “surround,” “to surround,” and “surrounding” may include not only entirely surrounding but also approximately surrounding. In addition, exposing may include not only entirely exposing but also exposing at least a portion of a structure, and exposure may mean exposing a component from another component in which the component is buried. In addition, being adjacent to each other may mean that at least some components, among components, are in contact with each other.

As used herein, a process error or a positional deviation occurring in a manufacturing process, an error in measurement, and the like may be included. For example, “substantially perpendicular” may include not only “completely perpendicular,” but also “approximately perpendicular.” In addition, “substantially coplanar” may include not only “completely coplanar,” but also “approximately coplanar.”

As used herein, “in cross-section” may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, thickness, width, length, depth, line width, space, pitch, and the like may be measured using a scanning microscope or an optical microscope based on a cross-section obtained by polishing or cutting a printed circuit board. The cross-section may be a vertical cross-section or a horizontal cross-section, and each value may be measured based on the required cross-section. For example, a width of an upper end and/or lower end of a via may be measured in cross-section taken along a central axis of the via. When the value is not constant, the value may be determined as an average value of values measured at five arbitrary points. A minimum value may be determined as a smallest value in a corresponding layer or a corresponding region.

As used herein, the term “an example” does not mean the same example embodiment, and is provided to emphasize different unique features. However, the examples presented above do not preclude implementation in combination with features of other examples. For example, a context described in a specific example may be used in other examples, even if it is not described in the other example examples, unless it is described contrary to or inconsistent with the context in the other examples.

The terms used herein describe particular examples only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a substrate having first and second external portions opposite to each other in a length direction;
a first insulating layer disposed on an upper side of the substrate;
a second insulating layer disposed on a lower side of the substrate;
a first insulating material covering at least a portion of the first external portion of the substrate; and
a second insulating material covering at least a portion of the second external portion of the substrate,
wherein the first and second insulating layers have a coefficient of thermal expansion higher than that of the substrate, and
the first and second insulating materials have a coefficient of thermal expansion lower than that of the substrate.

2. The printed circuit board of claim 1, wherein
the first insulating material includes a first-first insulating material disposed on an upper side of the first external portion, and a first-second insulating material disposed on a lower side of the first external portion, and
the second insulating material includes a second-first insulating material disposed on an upper side of the second external portion, and a second-second insulating material disposed on a lower side of the second external portion.

3. The printed circuit board of claim 2, wherein
the first-first and first-second insulating materials are spaced apart from each other with the first external portion interposed therebetween, and
the second-first and second-second insulating materials are spaced apart from each other with the second external portion interposed therebetween.

4. The printed circuit board of claim 3, wherein
the first and second external portions of the substrate respectively have first and second protrusion portions,
a thickness of each of the first and second protrusion portions is less than a thickness of a remaining region of the substrate excluding the first and second protrusion portions,
the first-first insulating material is disposed between the first protrusion portion and the first insulating layer,
the first-second insulating material is disposed between the first protrusion portion and the second insulating layer,
the second-first insulating material is disposed between the second protrusion portion and the first insulating layer, and
the second-second insulating material is disposed between the second protrusion portion and the second insulating layer.

5. The printed circuit board of claim 4, wherein at least a portion of an external surface of each of the first and second protrusion portions and at least a portion of an external surface of each of the first and second insulating layers are exposed from the first and second insulating materials.

6. The printed circuit board of claim 3, wherein
the first-first insulating material is disposed on an upper surface of the first external portion of the substrate to cover at least a portion of an external surface of the first insulating layer,
the first-second insulating material is disposed on a lower surface of the first external portion of the substrate to cover at least a portion of an external surface of the second insulating layer,
the second-first insulating material may be disposed on an upper surface of the second external portion of the substrate to cover at least another portion of the external surface of the first insulating layer, and
the second-second insulating material is disposed on a lower surface of the second external portion of the substrate to cover at least another portion of the external surface of the second insulating layer.

7. The printed circuit board of claim 6, wherein at least a portion of an external surface of each of the first and second external portions of the substrate is exposed from the first and second insulating materials.

8. The printed circuit board of claim 1, further comprising:
a plurality of first wiring layers disposed in the first insulating layer;
a plurality of first via layers disposed in the first insulating layer, the plurality of first via layers respectively connected to at least one of the plurality of first wiring layers;
a plurality of second wiring layers disposed in the second insulating layer; and
a plurality of second via layers disposed in the second insulating layer, the plurality of second via layers respectively connected to at least one of the plurality of second wiring layers.

9. The printed circuit board of claim 8, further comprising:
at least one through-via passing through the substrate,
wherein at least a portion of a lowermost first via layer, among the plurality of first via layers, is connected to an upper side of the through-via, and
at least a portion of an uppermost second via layer, among the plurality of second via layers, is connected to a lower side of the through-via.

10. The printed circuit board of claim 1, wherein the substrate includes a glass substrate having a coefficient of thermal expansion in a range from 6 ppm/° C. to 10 ppm/° C.

11. The printed circuit board of claim 10, wherein the first and second insulating layers includes an Ajinomoto build-up film (ABF) having a thermal expansion coefficient higher than 10 ppm/° C.

12. The printed circuit board of claim 10, wherein the first and second insulating materials respectively includes a prepreg (PPG), an ABF, or ceramic having a coefficient of thermal expansion of less than 6 ppm/° C.

13. A printed circuit board comprising:
a substrate having first and second external portions opposite to each other in a length direction;
a first insulating layer disposed on an upper side of the substrate;
a second insulating layer disposed on a lower side of the substrate;
a first insulating material covering at least a portion of the first external portion of the substrate; and
a second insulating material covering at least a portion of the second external portion of the substrate,
wherein at least a portion of an external surface of each of the first and second external portions of the substrate is exposed from the first and second insulating materials.

14. The printed circuit board of claim 13, wherein
the first insulating material includes a first-first insulating material disposed on an upper side of the first external portion, and a first-second insulating material disposed on a lower side of the first external portion, and,
the second insulating material includes a second-first insulating material disposed on an upper side of the second external portion, and a second-second insulating material disposed on a lower side of the second external portion,
the first-first and first-second insulating materials are spaced apart from each other with the first external portion interposed therebetween, and
the second-first and second-second insulating materials are spaced apart from each other with the second external portion interposed therebetween.

15. The printed circuit board of claim 14, wherein
the first and second external portions of the substrate respectively have first and second protrusion portions,
a thickness of each of the first and second protrusion portions is less than a thickness of a remaining region of the substrate excluding the first and second protrusion portions,
the first-first insulating material is disposed between the first protrusion portion and the first insulating layer,
the first-second insulating material is disposed between the first protrusion portion and the second insulating layer,
the second-first insulating material is disposed between the second protrusion portion and the first insulating layer, and
the second-second insulating material is disposed between the second protrusion portion and the second insulating layer.

16. The printed circuit board of claim 14, wherein
the first-first insulating material is disposed on an upper surface of the first external portion of the substrate to cover at least a portion of an external surface of the first insulating layer,
the first-second insulating material is disposed on a lower surface of the first external portion of the substrate to cover at least a portion of an external surface of the second insulating layer,
the second-first insulating material is disposed on an upper surface of the second external portion of the substrate to cover at least another portion of the external surface of the first insulating layer, and
the second-second insulating material is disposed on a lower surface of the second external portion of the substrate to cover at least another portion of the external surface of the second insulating layer.

17. The printed circuit board of claim 13, further comprising:
a plurality of first wiring layers disposed in the first insulating layer;
a plurality of first via layers disposed in the first insulating layer, the plurality of first via layers respectively connected to at least one of the plurality of first wiring layers;
a plurality of second wiring layers disposed in the second insulating layer; and
a plurality of second via layers disposed in the second insulating layer, the plurality of second via layers respectively connected to at least one of the plurality of second wiring layers; and
at least one through-via passing through the substrate,
wherein at least a portion of a lowermost first via layer, among the plurality of first via layers, is connected to an upper side of the through-via, and
at least a portion of an uppermost second via layer, among the plurality of second via layers, is connected to a lower side of the through-via.

18. The printed circuit board of claim 13, wherein
the substrate includes a glass substrate having a coefficient of thermal expansion in a range from 6 ppm/° C. to 10 ppm/° C.,
the first and second insulating layers includes an Ajinomoto build-up film (ABF) having a thermal expansion coefficient higher than 10 ppm/° C., and
the first and second insulating materials respectively includes a prepreg (PPG), an ABF, or ceramic having a coefficient of thermal expansion less than 6 ppm/° C.
